(19) United States
(12) Patent Application Publication
(10) Pub. No.: US 2025/0298054 A1
(43) Pub. Date: Sep. 25, 2025

(54) TIP STRUCTURE AND CONTACT PIN

(71) Applicant: Enplas Corporation, Kawaguchi-shi (JP)

(72) Inventor: Takahiro ODA, Kawaguchi-shi (JP)

(21) Appl. No.: 19/065,148

(22) Filed: Feb. 27, 2025

(30) Foreign Application Priority Data
Mar. 22, 2024 (JP) 2024-046513

(51) Int. Cl. G01R 1/067

(52) U.S. Cl. CPC G01R 1/06761; G01R 1/06738

(57) ABSTRACT

The tip structure of the present invention is a tip structure including an apex that is for contact to be used for conduction confirmation, and the tip structure includes a base material that includes an edge and is made of an iron alloy having a Cr content of 3 mass % or more; and a conductive layer that covers the base material. In the tip structure, the apex has a minimum curvature radius of 5 μm or less.

### CROSS REFERENCE TO RELATED APPLICATIONS

This application is entitled to and claims the benefit of Japanese Patent Application No. 2024-046513, filed on Mar. 22, 2024, the disclosure of which including the specification, drawings and abstract is incorporated herein by reference in its entirety.

### TECHNICAL FIELD

The present invention relates to a tip structure and a contact pin including the tip structure.

### BACKGROUND ART

When inspecting electrical components such as IC packages, quality control is performed by confirming conduction. For example, Patent Literature (hereinafter, referred to as PTL) 1 discloses an electrical connection inspection device for confirming the electrical connection by electrically contacting an object to be inspected.

### CITATION LIST

### Patent Literature

PTL 1
Japanese Patent No. 4045084

### SUMMARY OF INVENTION

### Technical Problem

A contact pin is known as a component of an inspection device used to confirm conduction. A contact pin includes a tip portion, and the tip portion comes into contact with an object to be inspected to confirm conduction. Specifically, the tip portion of the contact pin includes an apex, and the apex comes into contact with a solder ball of an IC chip, thereby confirming the conduction.

Conventionally, beryllium copper (BeCu) or carbon tool steel (SK material) has been used as the base material for the tip portion of a contact pin. When such a BeCu or SK material is used as the base material, an edge is formed at the BeCu or SK material, and a region including the edge is first nickel-plated and then gold-plated to form the apex. At this time, since BeCu and SK materials are not corrosion-resistant materials, oxidation may progress to the inside. Therefore, it was necessary to carry out strong chemical polishing to remove an oxidized portion as a pretreatment for plating. However, performing strong chemical polishing erodes the base material, causing the edge curvature radius to increase to approximately 10 μm. When the curvature radius of an edge becomes large, it becomes difficult for the edge covered with plating, namely the apex of the tip portion, to bite into the solder ball, making it impossible to stably inspect the conduction.

Palladium alloys are also known as base materials for the tip portions of contact pins. When a palladium alloy is used as the base material, there is no need to perform plating or perform chemical polishing. Therefore, when a palladium alloy is used as the base material, the edge formed on the base material can be used as the apex for contact as it is, and therefore the curvature radius of the apex becomes small. However, palladium is easily alloyed with tin in a solder ball and thus is easily worn away. Therefore, when the apex of a contact pin made of a palladium alloy is repeatedly brought into contact with a solder ball, the curvature radius of the apex becomes large, making it impossible to stably inspect the conduction.

An object of the present invention is to provide a tip structure that has a small curvature radius at the apex thereof and that can maintain the small curvature radius at the apex, and a contact pin including the tip structure.

### Solution to Problem

The present invention relates to a tip structure and a contact pin including the tip structure as follows.
[1] A tip structure including an apex that is for contact to be used for conduction confirmation, the tip structure including: a base material that includes an edge and is made of an iron alloy having a Cr content of 3 mass % or more; and a conductive layer that covers the base material,
   in which the apex has a minimum curvature radius of 5 μm or less.
[2] The tip structure according to [1], in which the conductive layer contains at least one metal selected from the group consisting of gold, silver, tin, and platinum group metals.
[3] The tip structure according to [1] or [2], in which the conductive layer includes two or more layers.
[4] The tip structure according to [2] or [3], in which the conductive layer further contains at least one metal selected from the group consisting of palladium, cobalt, and nickel.
[5] The tip structure according to any one of [1] to [4], further including a nickel layer between the base material and the conductive layer.
[6] The tip structure according to any one of [1] to [5], in which the base material has a Vickers hardness of 400 HV or more.
[7] The tip structure according to any one of [1] to [6], in which the conductive layer has a Vickers hardness of 1000 HV or less.
[8] A contact pin including the tip structure according to any one of [1] to [7].

### Advantageous Effects of Invention

The present invention can provide a tip structure that has a small curvature radius at the apex thereof and that can maintain the small curvature radius at the apex, and a contact pin including the tip structure.

### BRIEF DESCRIPTION OF DRAWINGS

FIG. 1 illustrates a contact pin;

FIG. 2 is a partial cross-sectional view of the tip structure in the contact pin; and

FIG. 3A illustrates the results of a wear resistance test of an example, and FIG. 3B illustrates the results of the wear resistance test of a comparative example.

### DESCRIPTION OF EMBODIMENTS

### Contact Pin

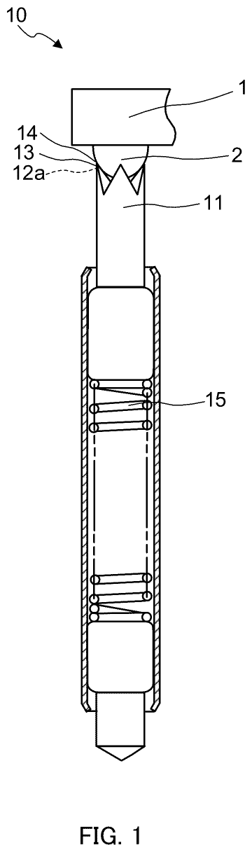

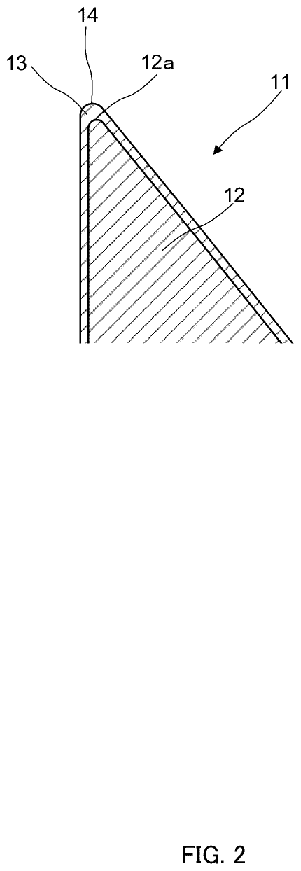

FIG. 1 illustrates contact pin 10. As illustrated in FIG. 1, contact pin 10 includes tip structure 11. FIG. 2 is a partial cross-sectional view of tip structure 11. As illustrated in FIG. 2, tip structure 11 includes apexes 14 that are used for confirming conduction. Tip structure 11 includes base material 12 made of an iron alloy (for example, stainless steel) having a Cr content of 3 mass % or more, and conductive layer 13 covering base material 12 (edge 12a). The minimum curvature radius of apex 14 is 5 μm or less, and more preferably the minimum curvature radius of apex 14 is 4 μm or less. With the minimum curvature radius of apex 14 being 5 μm or less, apex 14 can easily bite into solder ball 2, and conduction confirmation can be performed stably. The minimum curvature radius of apex 14 can be measured with a laser microscope.

The “apex” described herein not only refers to a state formed by conductive layer 13, but also includes, for example, a state in which conductive layer 13 is worn away and base material 12 (edge 12a) is exposed from conductive layer 13. In other words, the “apex” refers to the location (at a contact pin) which comes into contact with solder ball 2 of IC chip 1. The number of apexes 14 may be one or more than one. In the present embodiment, tip structure 11 and contact pin 10 include a plurality of apexes 14.

Contact pin 10 configured to include tip structure 11 as described above can easily bite into, for example, solder ball 2 of IC chip 1 as illustrated in FIG. 1, and therefore conduction can be stably confirmed. Contact pin 10 includes tip structure 11 as one end portion thereof, and also includes the other end portion located opposite to the tip structure.

The two end portions are electrically connected to each other, and the length between the two end portions changes as biasing member (spring) 15 expands and contracts. Contact pin 10 can be used while being supported by a support (socket).

Hereinafter, base material 12 and conductive layer 13 in tip structure 11 of contact pin 10 will be described in detail below.

### Base Material

Base material 12 is made of an iron alloy having a Cr content of 3 mass % or more, and is preferably made of, for example, stainless steel. In the present embodiment, base material 12 includes edge 12a and forms apex 14 together with conductive layer 13. Stainless steel herein refers to stainless steel as defined in JIS G0203 4.3.8. That is, stainless steel is a steel having a Cr (chromium) content of 10.5 mass % or more and a carbon content of 1.2 mass % or less.

In the present invention, the type of stainless steel is not particularly limited. Examples of types of stainless steel include austenitic stainless steel, martensitic stainless steel, and the like.

The iron alloy of base material 12 may have a Cr content of 3 mass % or more, preferably a Cr content of 10.5 mass % or more, and more preferably of 13 to 15 mass %. The iron alloy of base material 12 preferably has a carbon content of 1.2 mass % or less, and more preferably 0.1 mass % or more.

Base material 12 made of an iron alloy having a Cr content of 3 mass % or more has a passive film on the surface thereof, and oxidation does not progress to the inside of base material 12. Therefore, for example, for covering the surface of base material 12 with conductive layer 13 by plating or the like, there is no need to perform strong chemical polishing as a pretreatment. Using base material 12 made of an iron alloy having a Cr content of 3 mass % or more thus can adjust the curvature radius of edge 12a to be small, and the curvature radius of apex 14 can also be maintained small when the base material is covered with conductive layer 13.

After conductive layer 13 is formed on the surface of the base material, in order to improve the conduction of base material 12 made of an iron alloy having a Cr content of 3 mass % or more, it is preferable that the base material does not include a passive film on the surface thereof. The passive film is present thinly on the surface of a untreated base material 12 made of an iron alloy having a Cr content of 3 mass % or more. Therefore, a surface treatment such as strong chemical polishing is not necessary as a pretreatment before covering the base material with conductive layer 13, but it is preferable to carry out a surface treatment such as weak chemical polishing to a degree sufficient to remove the passive film. The surface treatment (for example, chemical polishing) may be performed as necessary, but does not have to be performed.

The curvature radius of edge 12a formed on base material 12 may be appropriately adjusted in such a way that when edge 12a is covered with conductive layer 13, the minimum curvature radius of apex 14 (conductive layer 13 covering edge 12a) becomes 5 μm or less. Therefore, the minimum curvature radius of edge 12a is preferably less than 5 μm, and more preferably less than 4 μm. The minimum curvature radius of edge 12a can be measured with a laser microscope.

The number of edges 12a in base material 12 may be one or more than one. In the present embodiment, base material 12 includes a plurality of edges 12a.

Base material 12 made of an iron alloy having a Cr content of 3 mass % or more preferably has a Vickers hardness of 400 HV or more, and more preferably 500 HV or more. By setting the Vickers hardness to 400 HV or more, wear of edge 12a of in base material 12 can be reduced.

Base material 12 made of an iron alloy having a Cr content of 3 mass % or more may be either quenched or unquenched. Quenching can be used to allow base material 12 made of an iron alloy having a Cr content of 3 mass % or more to have a desired Vickers hardness. In the case where base material 12 is quenched, the Vickers hardness (400 HV or more) of base material 12 means the Vickers hardness after the quenching. Therefore, the Vickers hardness of base material 12 before the quenching may be less than 400 HV. The Vickers hardness of base material 12 can be measured in accordance with JIS Z2244:2009.

An iron alloy having a Cr content of 3 mass % or more becomes hard and difficult to machine when the iron alloy contains silicon, making it difficult to form edge 12a. For this reason, it is preferable that an iron alloy having a Cr content of 3 mass % or more does not contain silicon. Specifically, the silicon content of then iron alloy having a Cr content of 3 mass % or less is preferably 1 mass % or less.

### Conductive Layer

Conductive layer 13 is a layer that covers base material 12 (edge 12a). Conductive layer 13 serves to reduce the electrical resistance of tip structure 11 (contact pin 10). It is preferable that conductive layer 13 covers at least edge 12a. In the present embodiment, conductive layer 13 covers the entire base material 12, which includes edge 12a. The minimum curvature radius of conductive layer 13 (apex 14) covering edge 12a is 5 μm or less, and more preferably 4 μm or less. This configuration allows conductive layer 13 (apex 14) covering edge 12a to easily bite into solder ball 2, making it possible to stably confirm the conduction. The minimum curvature radius of conductive layer 13 (apex 14) can be measured with a laser microscope.

The material constituting conductive layer 13 is not particularly limited as long as the material has conductivity that allows the conductive layer to function as an electrical contact. Specifically, examples of conductive layer 13 include layers containing at least one metal selected from the group consisting of gold (Au), silver (Ag), tin (Sn), platinum group metals (platinum (Pt), palladium (Pd), rhodium (Rh), iridium (Ir), ruthenium (Ru), and osmium (Os)), cobalt (Co), nickel (Ni), and bismuth (Bi).

Conductive layer 13 may be an alloy layer containing two or more of the above elements, for example, an alloy layer selected from the group consisting of Au—Co, Au—Ni, Au—Ag, Au—Sn, Pd—Co, Pd—Ni, Pd—Ag, Rh—Ru, Pt—Ir, Pt—Rh, Sn—Ag, Sn—Cu, and Sn—Bi.

Conductive layer 13 is preferably a layer containing one metal selected from the group consisting of gold (Au), silver (Ag), tin (Sn) and platinum group metals (platinum (Pt), palladium (Pd), rhodium (Rh), iridium (Ir), ruthenium (Ru), and osmium (Os)), a layer of an alloy containing palladium and cobalt (PdCo), or a layer of an alloy containing palladium and nickel (PdNi).

Furthermore, conductive layer 13 may be formed by laminating a plurality of layers, thereby including two or more layers. When conductive layer 13 is a laminate, the layer on the apex 14 side that contacts an electrical component is the conductive layer on the front surface (surface conductive layer), and the layer on the base material 12 side is the intermediate conductive layer. The surface conductive layer may be the layer described above as the conductive layer. The intermediate conductive layer may be a layer containing at least one metal selected from the group consisting of gold and palladium.

Conductive layer 13 may directly or indirectly cover edge 12a of base material 12 made of an iron alloy having a Cr content of 3 mass % or more. When conductive layer 13 indirectly covers edge 12a of base material 12 made of an iron alloy having a Cr content of 3 mass % or more, it is preferable that there is a nickel layer between edge 12a of base material 12 and conductive layer 13. The nickel layer may be used to prevent conductive layer 13 from peeling off from base material 12. More specifically, the nickel layer is formed by plating while removing the passive film of an iron alloy having a Cr content of 3 mass % or more (e.g., nickel plating while decomposing the passive film in a Wood's bath). A nickel layer, for example, allows for easier plating of a conductive layer than plating the conductive layer directly onto an iron alloy.

Covering base material 12 (edge 12a) with conductive layer 13 may be performed

by, for example, plating, vapor deposition, sputtering, or the like. Of these, it is preferable to cover base material 12 (edge 12a) with plating. The plating method is not particularly limited. Examples of the plating include electrolytic plating and electroless plating. In the case of covering base material 12 (edges 12a) with conductive layer 13 by plating, base material 12 including edge 12a may or may not be chemically polished as a pretreatment.

The Vickers hardness of conductive layer 13 is preferably 1000 HV or less. With a Vickers hardness of 1000 HV or less for conductive layer 13, conductive layer 13 is prevented from becoming brittle, and conductive layer 13 is prevented from cracking and peeling off from base material 12 which may be caused by a slight deformation of base material 12. The Vickers hardness of conductive layer 13 can be measured in accordance with JIS Z2244:2009.

The thickness of conductive layer 13 is preferably 0.01 μm or more in view of obtaining satisfactory conductivity, and is preferably 5 μm or less in view of preventing the excessive increase in the curvature radius.

### Effect

In tip structure 11 according to the present embodiment, base material 12 made of an iron alloy having a Cr content of 3 mass % or more includes edge 12a, and edge 12a is covered with conductive layer 13. This configuration allows apex 14 to have a small the curvature radius, at 5 um or less, thereby stabilizing the contact resistance. Furthermore, an iron alloy having a Cr content of 3 mass % or more is less expensive than a palladium alloy, and therefore, the costs of tip structure 11 and contact pin 10 including tip structure 11 can be reduced.

### EXAMPLES

### Wear Resistance Test

A wear resistance test was carried out on the apexes of the contact pins of the example and comparative example. The contact pin used in the example includes a base material made of stainless steel, and in the tip structure of the contact pin, the base material including an edge was directly plated with gold. The minimum curvature radius of the gold plating layer (apex) was 5 μm or less.

On the other hand, the contact pin of the comparative example includes a base material made of BeCu, and the base material including an edge was first chemically polished, then plated with nickel, and finally plated with gold to obtain a tip structure. The minimum curvature radius of the gold plating layer (apex) was 10 μm.

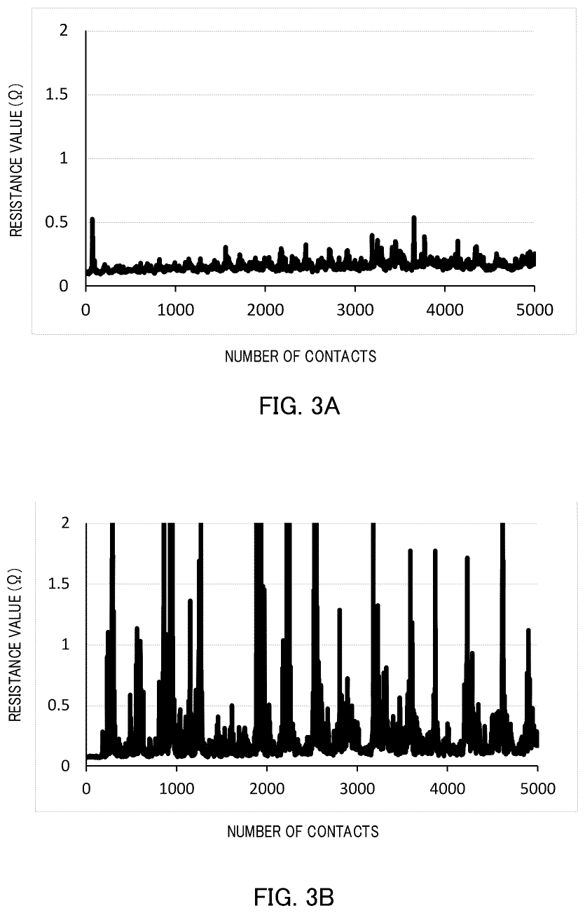

The tip structures of these contact pins were brought into contact with solder balls 5,000 times, and the resistance value was measured each time. During the test, new solder balls were used for each time. The measurement results of the example are shown in the graph of FIG. 3A, and the measurement results of the comparative example are shown in the graph of FIG. 3B.

As can be seen from FIGS. 3A and 3B, the resistance values were low in the example, and high in the comparative example. Moreover, the variation in resistance value was small in the example, whereas the variation in resistance value was large in the comparative example. The reason therefor can be considered that the minimum curvature radius of the gold layer (apex) in the example is smaller than that in the comparative example, so that the apex of the example is more likely to bite into the solder ball.

In addition, as can be seen from FIG. 3A, the resistance value remained small even after the number of contacts reached 5,000 in the example. This can be considered to indicate that the apex is not worn and the minimum curvature radius is maintained small, resulting in high wear resistance. Specifically, it can be considered that wear is reduced because there is less alloying between the tin in the solder ball and the gold-covered base material made of stainless steel. It is also considered that the base material made of stainless steel was not worn down by mechanical forces.

### Industrial Applicability

The present invention is capable of preventing the curvature radius of the apex from becoming large, and allows for stable conduction confirmation for a long period of time. Therefore, it is expected that the yield of electrical components and the like, namely objects to be inspected, can be improved.

### REFERENCE SIGNS LIST

1 IC chip
2 Solder ball
10 Contact pin
11 Tip structure
12 Base material
12a Edge
13 Conductive layer
14 Apex
15 Biasing member (spring)

1. A tip structure including an apex that is for contact to be used for conduction confirmation, the tip structure comprising:
a base material that includes an edge and is made of an iron alloy having a Cr content of 3 mass % or more; and
a conductive layer that covers the base material,
wherein
the apex has a minimum curvature radius of 5 um or less.

2. The tip structure according to claim 1, wherein the conductive layer contains at least one metal selected from the group consisting of gold, silver, tin, and platinum group metals.

3. The tip structure according to claim 1, wherein the conductive layer includes two or more layers.

4. The tip structure according to claim 2, wherein the conductive layer further contains at least one metal selected from the group consisting of palladium, cobalt, and nickel.

5. The tip structure according to claim 1, further comprising a nickel layer between the base material and the conductive layer.

6. The tip structure according to claim 1, wherein the base material has a Vickers hardness of 400 HV or more.

7. The tip structure according to claim 1, wherein the conductive layer has a Vickers hardness of 1000 HV or less.

8. A contact pin comprising the tip structure according to claim 1.
